(19) United States
(12) Patent Application Publication
(10) Pub. No.: US 2006/0102078 A1
(43) Pub. Date: May 18, 2006

(54) Wafer fab

(75) Inventors: Kevin P. Fairbairn, Los Gatos, CA (US); Hari Ponnekanti, San Jose, CA (US); Christopher Lane, Los Gatos, CA (US); Robert Edward Weiss, San Francisco, CA (US); Ian Latchford, Palo Alto, CA (US); Terry Bluck, Santa Clara, CA (US)

Correspondence Address: STANLEY Z COLE, 26620 ST FRANCIS ROAD, LOS ALTOS HILLS, CA, 94022, US

(73) Assignee: INTEVAC INC.

(21) Appl. No.: 10/991,722

(22) Filed: Nov. 18, 2004

(51) Int. Cl. C23C 16/00; H01L 21/306

(52) U.S. Cl. 118/719; 156/345.32

(57) ABSTRACT

Described is a method for manufacturing wafers and a manufacturing system in which the footprint is substantially contained in a size approximating the processing chambers. Single wafers move horizontally through the system and processing occurs simultaneously in groups of processing chambers. Various manufacturing processes employed in making semiconductor wafers are included as processing chambers in the system.

### FIELD OF THE INVENTION

This invention has to do with wafer fabrication and in particular with a modular system in a universal fab tool for wafer manufacturing.

### BACKGROUND OF THE INVENTION

Wafers were historically processed in batches. Thus a batch of wafers, in for example, a cassette were exposed to a process step. They were then removed from the equipment and the equipment was recycled for a next batch. Recycling involves delays and expenses since once the processing chamber is opened and exposed to atmospheric conditions, a pump down would be required before a next batch could be cycled or processed through the system. The batch would then be carried through a next process step. After years, the batch system progressed to single wafer processing units. A history of these developments is traced in U.S. Pat. No. 4,756,815, which also describes a sputter coating system operating in a single wafer, rather than the batch, mode. In essence the value produced working on a single wafer made it economically sound to change from batch processing to single wafer processing. Today it is typical to cluster process chambers around a central wafer handling system and transfer of wafers from the central area to a chamber for processing and then back to the central area where the wafer is likely carried to another chamber clustered around the central area for further processing. These tools may have included additional processes. As an example the tool described in U.S. Pat. No. 4,756,815, also includes heating and cooling process steps in addition to sputtering. However, such combinations of processes tended to be interrelated to the main or key process of the equipment in that the heating and/or cooling steps supplemented the sputtering processes performed in the equipment. Examples of other dedicated units are described in U.S. Pat. Nos. 5,186,718 and 5,855,681. Because these tools, generally used in industry today tend to be single function units, i.e., they perform sputtering or physical vapor deposition or they perform chemical vapor deposition (CVD), or etch, or ion implantation, etc., manufacturers may be compelled to purchase individual tools for each processing step to be used in making an ultimate semiconductor device. Because of wafer transfer and other wafer handling considerations in going from equipment to equipment, the need for ultra clean clean-rooms developed and this, plus the large footprint occupied by the multiple machines or tools, operating within the clean room increased further the need for expensive and special facilities and in turn the expense of manufacturing in the wafer fab area. Applied Materials, a leading manufacturer of semiconductor manufacturing equipment, as an example, lists in excess of 10 different machines in a Product Overview on its website. Each is intended for use in fab lines with each unit practicing a different process. In addition these units may cost in excess of a few million dollars per unit and needless to say there are other manufacturers of semiconductor manufacturing equipment offering other units for different processes for processing wafers which are also used in the fab line. Setting up a new fab line today can cost two or more billion dollars, a significant investment for any business.

In general, single wafer processing systems in use today, are based upon clustering process chambers around central wafer handling systems. As discussed such systems are inefficient in use of space on the manufacturing floor and particularly in clean rooms. They are also inefficient in achieving objectives of processing wafers in that in these units the wafer handling subsystems as opposed to the processing subsystems occupy 50% or more of the system as well as its floor area. Additionally, wafers in the handling portions of the equipment are usually dealt with using robots and robots can bottleneck the system's net throughput. Also wafer sequencing from one chamber to another is inherently not ideal from a production rate point of view. There are also limits to adding processing stations. In one respect, this may be due to the number of outlets on the central section and on the other, this may be due to the limits of physical space around this central segment. The fact that the associated chambers tend to act independently of one another makes it difficult to share auxiliary components such as pumps, mass flow controllers or power generators. Also since the chambers are all tied into the central compartment, there is a real risk of cross contamination as to require limits on the number of processes that can be integrated into a single tool.

### SUMMARY OF THE INVENTION

The invention described addresses these problems. It reduces space required for the wafer transport subsystem so that it does not occupy physical floor space or a footprint beyond that occupied by the processing subsystems. In essence wafer handling mechanism is within the space generally occupied by the processing stations. The system includes multiple chambers and wafers are transported from chamber to chamber in a series and parallel sense as will be described in more detail hereinafter. At an early point, such as at the point of entry of the wafer into the load lock, wafers are combined with a supporting chuck and the wafer travels through the system back to the load lock in position on the chuck. This has an effect of lowering costs and preventing breakage in the processing of thin substrates. Transport of wafers between chambers takes place in series in the sense that a wafer passes from a processing chamber to the next adjacent processing chamber and in parallel in that all wafers in a row of chambers are moved at the same time by moving all wafers at once from chamber to chamber, and transfer of wafer between chambers does not otherwise occur. In addition the time of treatment within chambers is the same for each chamber. Additionally, the equipment may be structured for the same process or for more than a single process or for an insulating chamber to completely separate operating processes. It is also possible to obtain the benefits of sharing auxiliary equipment such as pumps or gas supplies between multiple chambers and these units can be in used in multiple chambers simultaneously or separately. It is also possible to set up the system so that power supplies, gas control are shared between process chambers. Thus the tool is capable of performing, as an example, sputtering or physical vapor deposition only, or, other processes such as chemical vapor deposition only, etch only, metalization only, ion implantation only, etc., or all of these processes simultaneously on the same frame in the same system. These processes may have independent supports or may have supports based on a sharing arrangement. The tool may have multiple chambers for a single process and these may follow one another or may be spaced with other operations in between. This can all be achieved without contamination of the wafer or the process chambers. Chambers may be separated one from another using valves between chambers, which operate when a wafer leaves a chamber and another enters. It is also possible to feed a wafer through sequential chambers and achieve lower vacuums in the following chambers with less pump down between processes in the system by controlling pressure in the central control system for the equipment. Chambers may also be added for additional processing with substantially no limit. The limit to expansion tends to be the overall length of the tool. In essence at some point it is desirable to consider a second tool.

Although the emphasis in the description of this invention throughout will be working with wafers for treatment by the various processes described, it should be appreciated that one can also work on other substrates such as diced wafers, diced wafers on tape, whole wafers on tape, optical disks, flat panels and solar cells among other such thin substrate layers. Accordingly, although the description is in terms of wafers, it should be understood that any one of these other substrates may be substituted for such wafers for processing in accordance with this invention.

### BRIEF DESCRIPTION OF THE DRAWINGS

For a better understanding of the present invention, reference is made to the accompanying drawings, which are incorporated herein by reference, and in which:

FIG. 1 is a schematic view of a 20 station system in accordance with this invention.

FIG. 2 is a schematic top view of the 20 station system of FIG. 1 showing the chambers of the system.

FIG. 3 is a schematic view of an illustrative four station system in accordance with this invention.

FIGS. 4A-4J are illustrative of operation of a 4 station system.

FIG. 5 is a schematic view of a sputter station.

FIG. 6 is a cutaway view of a sputter chamber.

FIG. 7 is a schematic illustration of the raising of a wafer into a process station, which, for example, may be a metalization chamber.

FIG. 8, A, B, and C schematically illustrates disk handling mechanism.

FIG. 9 is a schematic illustration of the shuttle chamber.

### DETAILED DESCRIPTION OF THE INVENTION

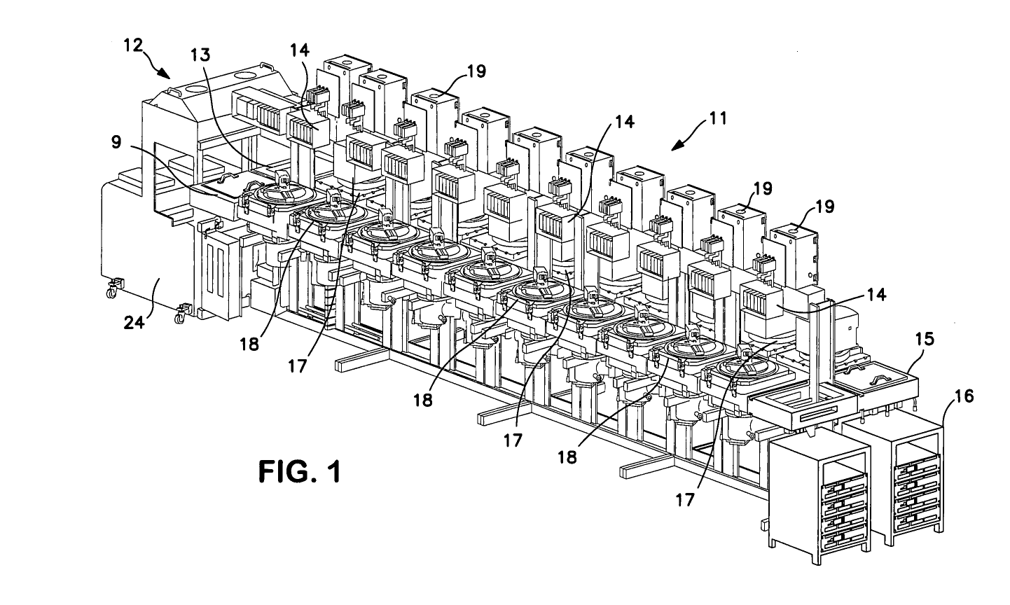

Referring now to FIG. 1, there is shown as an example of an embodiment of this invention, a 20 station system. Although in this Figure, a certain number of stations are shown, it should be understood that this invention may be practiced in a system with more or less stations depending on the needs at the installation. Also different stations are illustrated on the left side compared to the right side (which in the Figure appears as in the rear or in the front, respectively). However, a selection of stations may be made other than the ones shown and the unit will function in accordance with its intended purpose. In this Figure, 11 represents the 20 station system. The front end of the system 12 is where load lock 13 is located. At the opposite end is a transverse or shuttle chamber 15 and power supplies 16 for the process chambers, transport systems and other mechanisms of the system. In this Figure, like appearing process modules 17, appear along the left side viewing from the front end 12. Although only a few are marked with a number, the entire side may, again depending on the customer's needs, include the same processing modules, as is illustrated in this Figure. On the other side, a different set of process modules 18 are shown. Here again like appearing modules are shown and only a few are marked with the number 18. However, they may all comprise the same type of module and thus may be used for the same form of processing or they may comprise different modules for a different processing step, again depending on the desires of the customer for the installation. In this Figure the process modules shown are for illustrative purposes only. In fact process modules 17 are a typical representation of a module that maybe used for sputter cleaning or etching. A gas cabinet 19 for use in the module is seen positioned above each of the sputter or cleaning process chambers 17. Process modules 18 are illustrated as typical physical vapor deposition processing modules. However, it should be understood that these showings are intended only as representative and only for illustrative purposes and that modules for other processes may and are likely to be included in the system as determined by each user. Modules in the system can also be exchanged with other modules by the user, from time to time, to change processing arrangements in the system.

In operation, a wafer will enter system 11 at load lock 13 located at front end 12. This is also shown in other Figures of this specification. At this point the wafer moves from atmospheric conditions into a vacuum environment. The wafer next moves to a processing chamber 17, where it will be cleaned and etched and put through other processes if desired. It will routinely move from chamber to chamber until it reaches transfer chamber 15 where the wafer moves from one of the paths of travel for processing (the left side) to the other path of travel (the right side) for processing along this new path. Thus, following entry into system 11, the wafer will move through process chambers 17 which, for example, may include sputter deposition subsystems or like process subsystems, again depending on the needs of the customer in accordance with the specifications for the system. The wafer then transfers in shuttle chamber 15 and returns along the other path of the system and through processing chambers 18 as for example where the wafer is exposed to deposition processes such as physical vapor deposition, ion implantation, or chemical vapor deposition for example. It will then move into pre load lock chamber 9 in preparation for entering into load lock 13 from which it exits the system. Power supply subsystems 16 provide power as required for the operations of the individual chambers in system 11 as well as is required to move the wafer into and through the system. Control boxes 14 (only some are marked in this Figure) provide for operations within the adjacent chambers including controlling the various parameters of the processes performed within the chambers as well as the vacuum conditions within the chambers, the movement of the wafers, etc. and connect into and are operated by computer controls 24,

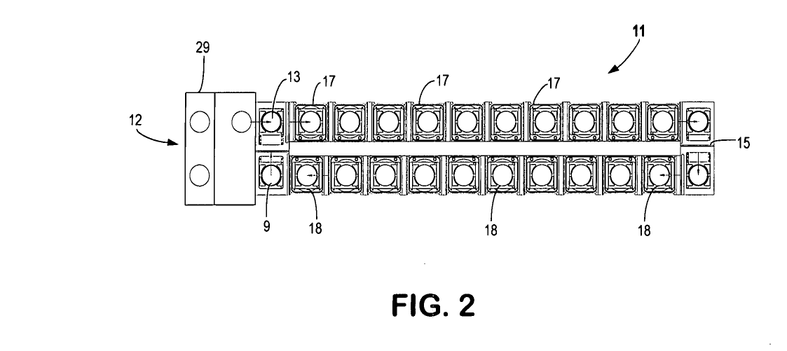

Referring now to FIG. 2, a wafer is loaded at front end 12 (the same numbers will generally be used to identify elements). The wafer may be placed into system 11 from a cassette of wafers placed at the position indicated as 29. Wafers are then fed one by one into the system. A new wafer enters at the front end 12 and is moved into load lock 13, following which it is moved sequentially through process chambers 17. For simplicity the entire left side of chambers (shown as the upper line of chambers in this Figure) shall be considered the same type of chamber for the same type of processing and each is identified as chamber 17. The wafer moves from the front end 12 through chambers 17 and eventually reaches transverse or shuttle chamber 15 where the wafer is moved from the left side to the right side of the system (shown as the lower row of chambers in this Figure). The chambers on the right side (lower level in this Figure) are all designated 18, again to simplify this explanation, but it should be understood that each chamber could support a different process if this is the desire of the user. In any event, a wafer after moving along the left side (shown as the upper row in FIG. 2) of chambers 17, moves to the chambers on the right side of system 11 (shown as the lower row in FIG. 2) by passing through the transverse or shuttle transfer chamber 15. The wafer then passes back sequentially through the chambers designated 18, to the pre load lock chamber 9 where it remains until it transfers into load lock 13. This transfer occurs when a wafer transfers out of load lock 13 and into the system by moving into the chambers on the left side of the system or into chambers designated 17. At that point the load lock is empty and the wafer from the pre load lock chamber 9 enters load lock 13 and then exits the machine at its front end 12 going from vacuum to atmosphere. At this point a new wafer can and does enter into load lock 13 and then into the processing chambers. The paths of chambers 17 and 18 are side by side so that the footprint for this system is substantially no bigger than the footprint for the chambers themselves. Transport of the wafers which generally occurs within the footprint of the processing chambers, the shuttle chamber and the load lock will be described in materials that follow. Arrows are included at points in this Figure to illustrate the direction of the movement of the wafer at that point in its cycle.

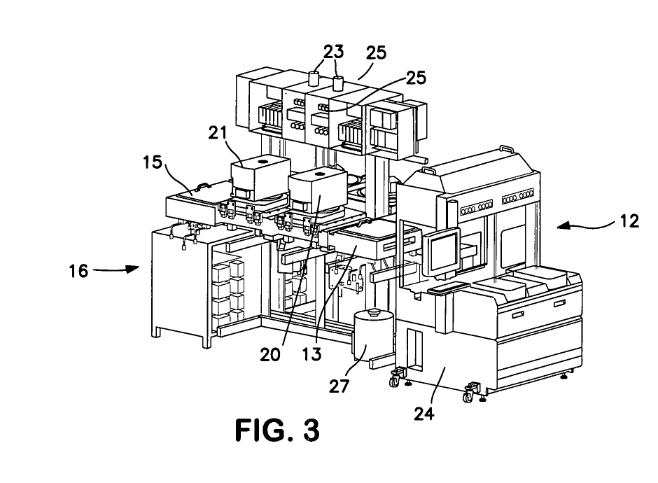

FIG. 3 shows a schematic view of a four station system. Some users may want systems to handle limited processing of wafers for one reason or another, and thus this Figure is useful in understanding the operation of a system of a smaller size. Importantly, however, this system also illustrates substantially all key components as well as transport paths of larger systems as to enable a more complete understanding of larger systems as well and it does so with less complications than are involved if one discusses the larger units. In FIG. 3, the front end is identified as 12. 20 represents an etch process chamber and 21 represents a sputter clean process chamber. 22 represents a physical vapor deposition chamber and 23 comprises exhaust gas ports. Input gas ports may be positioned adjacent to the exhaust ports 23. These ports are independently connected to individual gas boxes 25. 13 represents the load lock and 15 the shuttle or transverse chamber. 27 represent a vacuum pump. This pump is used to draw the vacuum in load lock 13. Processor power supplies 16 are shown on the rear of the system below transfer shuttle 15 and computers are housed in the compartment shown at 24.

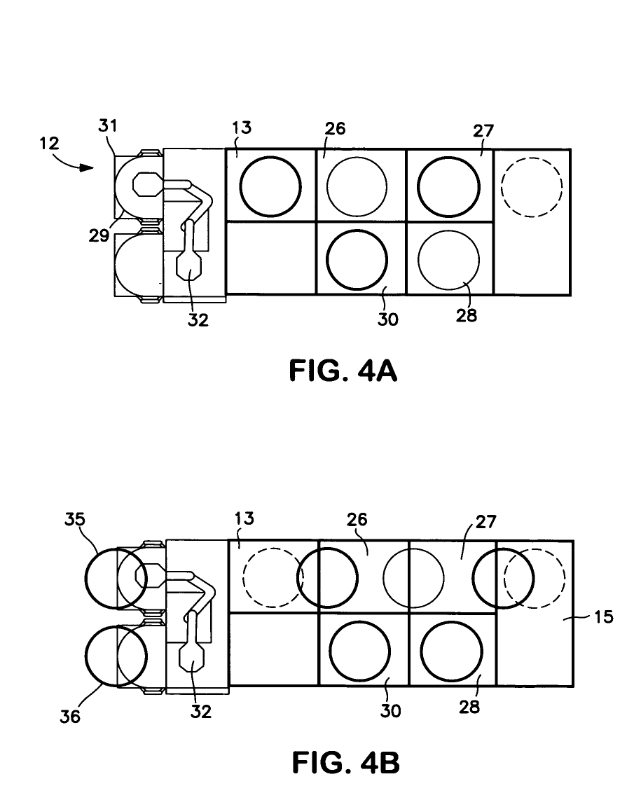

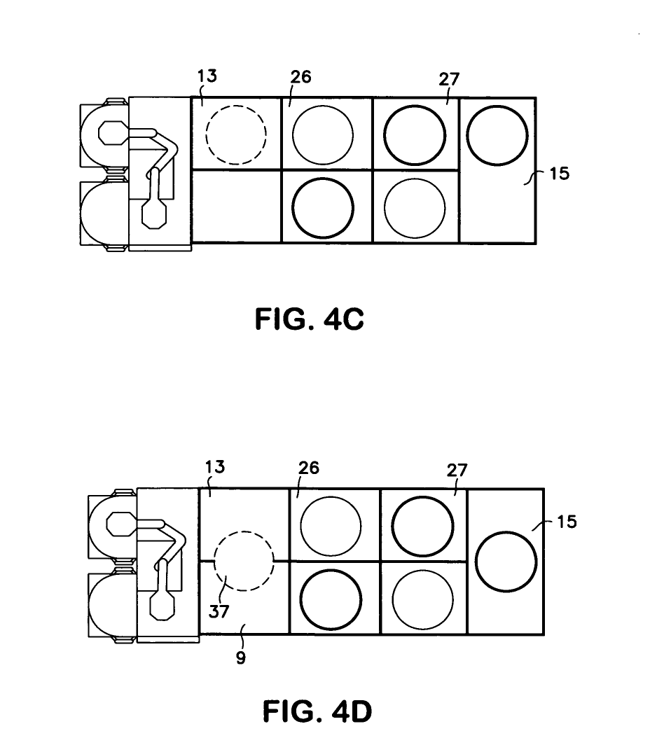

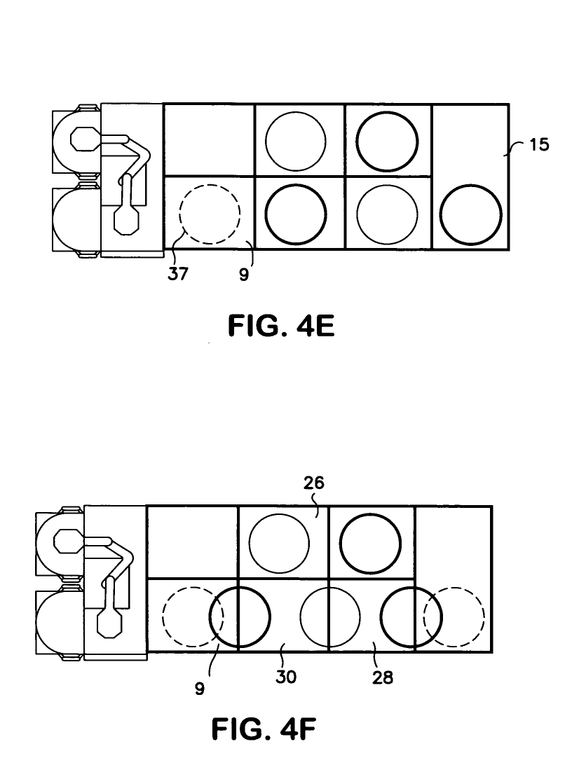

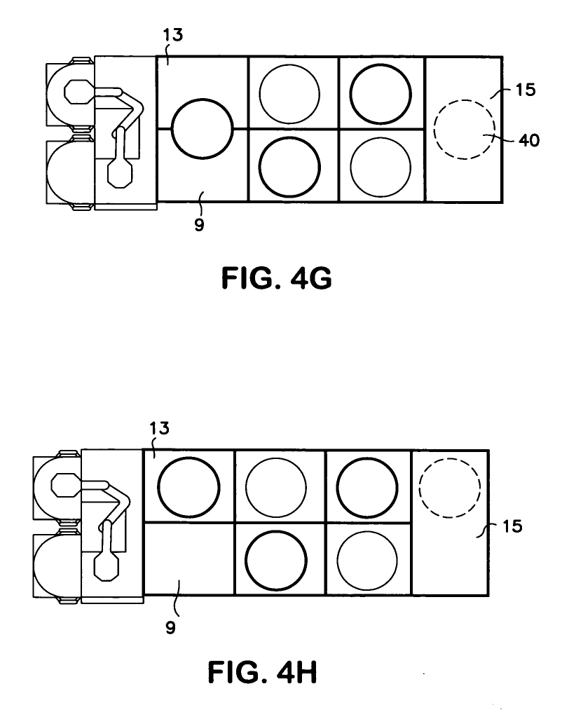

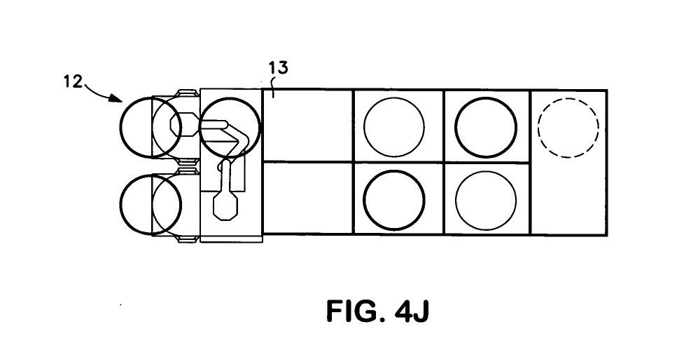

FIGS. 4A-J (with “I” omitted in the group A-J) illustrate stepwise movement of wafers through the system. It should be understood that the groups of wafers in this set of Figures move at the same time but all are not moved simultaneously. This will be discussed as the description of these Figures proceeds.

In FIG. 4A, there is shown a four-station system in which wafers are shown occupying the load lock 13, process chamber 26 and process chambers 27, 28 and 30. A front end 12 is also illustrated in this Figure. A structure for feeding wafers into the system is known in the art as a FOUP. This stands for front opening unified part that comprises an enclosure where wafers are housed and kept clean while waiting to enter the processing operations. This unit may also include, as is the case in this instance, feeding mechanism to place wafers into the system for processing and to take wafers from the system to be temporarily stored after processing. A cassette of wafers 29 is placed into this front end structure or FOUP 31 with the wafers in a horizontal position. Wafers are then transferred one by one from the cassette by blade 32 that lifts a wafer in the cassette and carries the wafer into load lock compartment 13.

FIG. 4A illustrates a beginning of a cycle. The wafer in load lock 13 is in the process of entering into the system. It is now within the vacuum of the system in load lock 13. The wafer in chamber 26 is being processed. As an example the wafer in chamber 26 is being etched. In chamber 27 another wafer, having passed through the etch chamber, is being cleaned for example for further processing. The wafer in chamber 28 is being coated with a metal in a first metal deposition chamber and the wafer in chamber 30 is being coated with a additional metal.

In FIG. 4B the wafers on the left side (shown as the top row in this Figure) within the system are shown as moving to the next stage. More particularly, the wafer in load lock 13 is shown being moved into etch process chamber 26 and the one in chamber 27 where cleaning occurs is seen moving into transfer shuttle 15. Two unprocessed wafers 35 and 36 are illustrated as waiting to be moved into the system. These are shown in these positions for illustrative purposes only since wafers normally will enter the system using a FOUP or some equivalent feeding device. The wafers undergoing processing in chambers 30 and 28 are shown as stationary. As is shown, there is no wafer present in the transverse chamber 15. Thus the system for the wafer movement for the left side chambers (shown as upper in this Figure) and for the right side chambers (30 and 28) can be set independently of each other. Thus wafers in the right side (lower row) can be treated for a time period twice that set for the left side (upper row in this Figure), or may move in sequence with the wafers being processed in the system or may be moved at any rate desired by the user to achieve the finished product of his or her own selection or determination.

In FIG. 4C, load lock 13 is shown as empty since the wafer that had been in this chamber has now moved to etch chamber 26. In general, wafers travel from and through chambers on a support. Wafers are placed onto supports or wafer carriers in load lock 13. Once a support becomes attached to a wafer, it remains with the wafer during its travels through the system.

The wafer that had previously been moving from the etch chamber 26 has now moved to chamber 27 where cleaning or surface treatment occurs. The wafer that had been moving from the cleaning chamber has now moved to the transverse transfer or shuttle chamber 15 where the wafer is transferred from one side to the other, which in this case is from the left side to the right side of the system. It is possible to change the wafer support or carrier as the wafer enters a transfer shuttle 15. Such a change might for example be made in order to avoid contamination of a process chamber based on prior exposure of the support as the wafer moves through the system. However, this is generally avoided by keeping any contaminated surface out of the processing chamber during processing of a wafer. The primary reason to change elements in the support system is when such elements have reached the end of their lives. In this Figure the wafer is moving from the left side of the system to its right side in shuttle chamber 15.

In FIG. 4D, wafers in chambers 26 and 27 are being processed. Also empty carrier 37 is shown moving from the load chamber 13 to a chamber that can be called the pre-load chamber 9 while the wafer that had been processed in the chambers on the left side of the system, in chambers 26 and 27, is shown moving from the left side to the right side of the system in transverse transfer or shuttle chamber 15. In FIG. 4E, the empty carrier 37 has reached pre load lock chamber 38 and the wafer in the transverse transfer chamber 15 has reached the right side of the system. Also at this same time the processing of wafers in the processing chambers on the right side of the system (lower row) has been completed.

In FIG. 4F, the wafers on the right side of the system (lower row) are shown in motion. More particularly, the processed wafer that has now been through all processing chambers and was last processed in the second metallization chamber 30 is shown moving into the pre load lock chamber 9. The wafer that had been transferred in the transverse transfer or shuttle chamber 15 is shown moving into the first metallization chamber 28 and the wafer that had previously been in the first metallization chamber 28 is shown moving into the second metallization chamber 30.

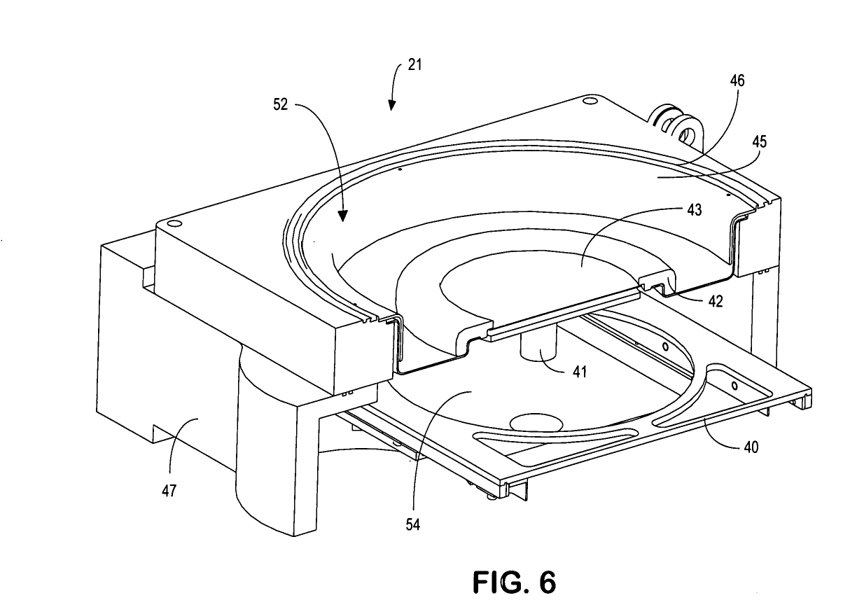

In FIG. 4G the support or carrier 40 in the transverse transfer or shuttle chamber 15 is shown moving to the left side of the system and the completed wafer in the pre load lock chamber 9 is shown moving into the load lock chamber 13. (See FIGS. 6 and 9 for a further illustration of carrier 40.) In FIG. 4H the support for the carrier has reached the left side of the system (shown at the top in this Figure) in the transverse transfer or shuttle chamber 15 and the fully processed wafer has completed its move from the pre load chamber 9 to the load lock chamber 13.

In FIG. 4J the finished wafer moves out of the load lock chamber 13 onto the blade in the FOUP (shown in FIG. 4A) where it is placed as a finished product into the cassette within the FOUP where it will remain while the other wafers required to fill the cassette are processed and then fed into the same cassette. The cassette will then be removed from front end 12. After the complete processing of a wafer and after it is returned to the cassette, the blade that returned the wafer to the cassette is used to lift another unprocessed wafer from the cassette and feed it into the system to start it on the path from chamber to chamber and back to the cassette as a fully processed wafer. Thus the cycle that has been explained starting at FIG. 4A is repeated for each wafer entering this system.

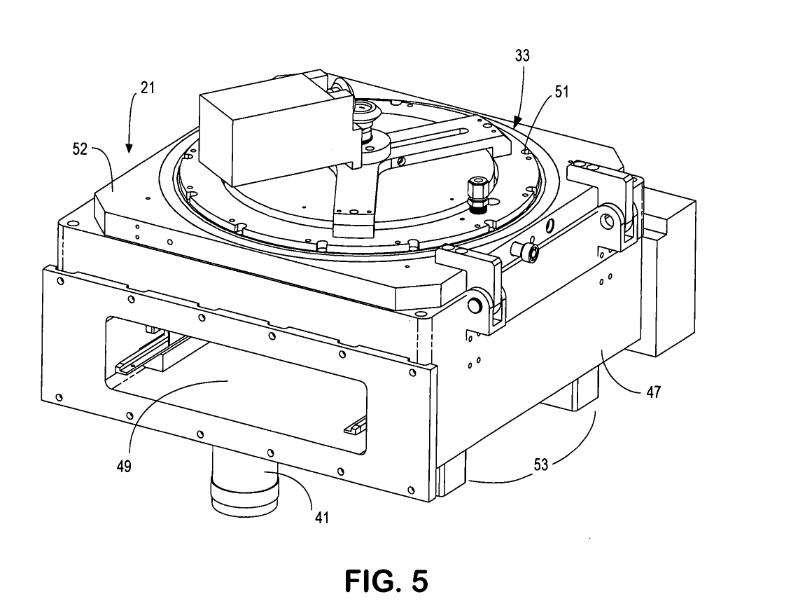

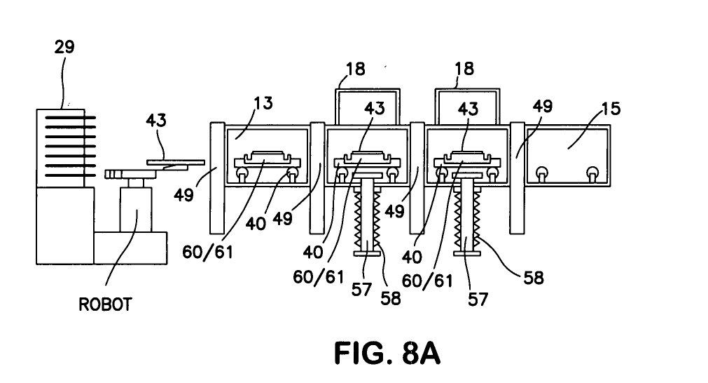

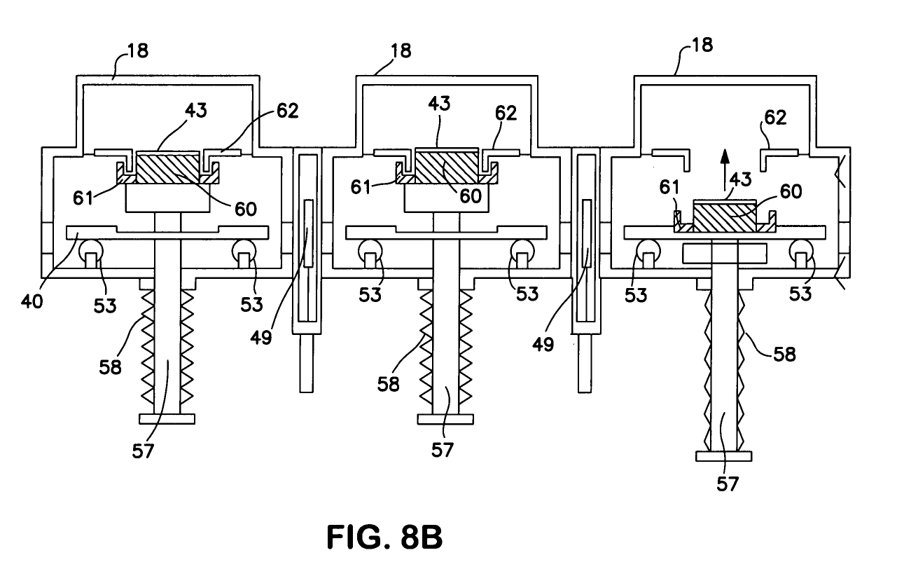

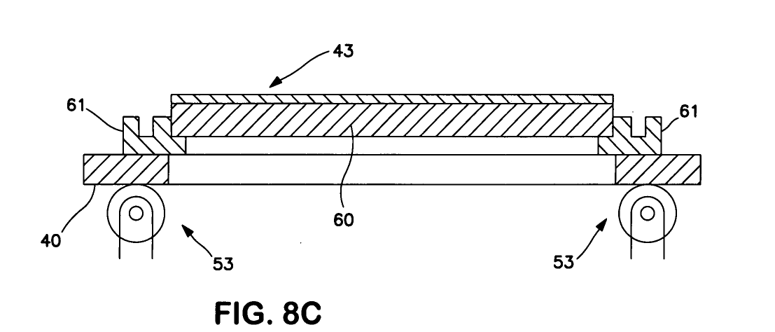

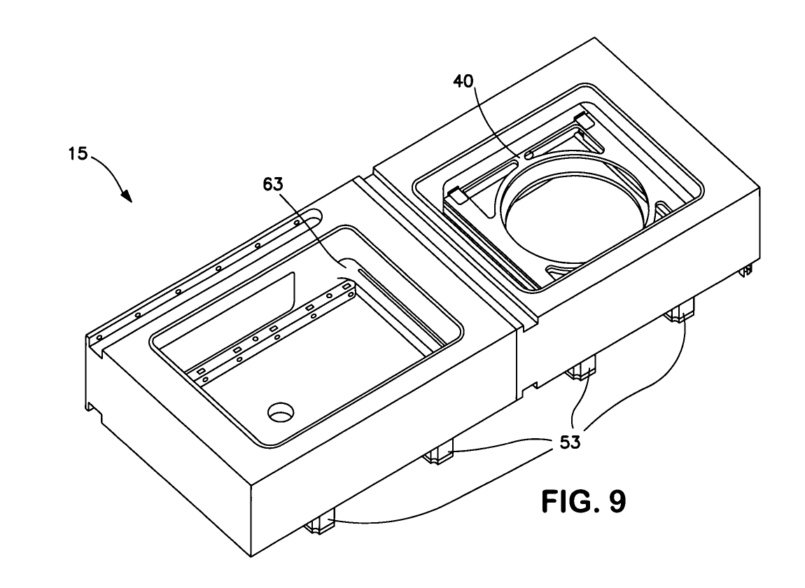

FIG. 5 is a schematic view of sputter station 21. A sputter station may be used as a processing chamber in the system of this invention to sputter deposit materials onto the surface of a wafer being processed. Such a station is shown for illustrative purposes since the particular processes included in a system will depend on the applications intended by the user. Thus in a given system, a physical vapor deposition processing chamber may or may not be included. If included, it may well look like sputter station 21. In this station is shown sputter chamber 52. At the base of the transfer chamber 47 is a drive mechanism 53 which may comprise a magnetic drive system including rollers, wheels and drive motors or equivalent mechanism to drive carrier 40 (see FIG. 6) on which the wafer rests during transfer into this chamber and then out of this chamber into the next chamber. The opening identified as 49 is the entrance (or alternatively could be the exit) for the carrier into sputter chamber 21. Extending downward below transfer chamber 47 in this Figure is an arm supporting pedestal 41, shown more clearly in FIG. 8, which comprises an arm extending downward from a pedestal 41. The pedestal is used to elevate the wafer upwardly during processing substantially sealing the sputter chamber 52 between the sputter source 51 across the top and generally the wafer 43 (see FIG. 8) across the bottom. This structure will support conditions required in the sputter chamber during sputtering operations. In general this means maintaining an appropriate vacuum and feeding a seeding gas into the chamber to facilitate sputtering as is well known in the art.

FIG. 6 is a partial cutaway view of sputter process chamber 21. Carrier 40 transfers the wafer in transfer chamber 47 into and out of sputter process chamber 21 where the wafer is carried through physical vapor deposition processing. As illustrated the central portion of carrier 40 supports the wafer during transport through the system. In a station such as the one illustrated in FIG. 6, pedestal 41 raises wafer 43 out of carrier 40 and brings it into near contact with isolation ring 42 as more fully shown in FIG. 8. Shields 45, which are made to be replaceable, cover the sidewalls of the chamber where sputtering occurs. The shields become coated with sputtered materials and are replaced from time to time in order to avoid contamination from old deposited materials on the walls of the chamber onto layers newly sputtered in the chamber. Sputter source 51 (see FIG. 5) rests against sputter mount 46 thereby enclosing the chamber.

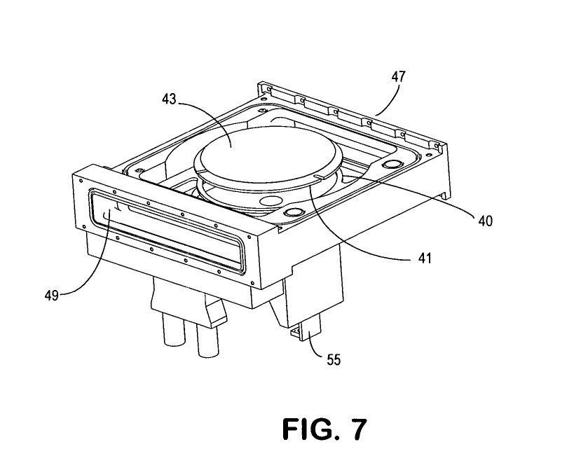

In FIG. 7 wafer 43 is shown in a raised position elevated to make near contact with isolation ring 42 (FIG. 6) in the process of positioning wafer 43 within the process chamber for processing. This process chamber may comprise a sputter chamber but it also may comprise an etch, CVD or cleaning chamber or other chamber of the system. Beneath wafer 43 is pedestal 41 and carrier 40. Passage or opening 49 permits the carrier to enter or leave transfer chamber 47. This module includes a like opening on the opposite side that cannot be seen in this view. Also shown in this figure is elevator lift 55 that raises pedestal 41 into position to press the wafer upwards in order to seal the sputtering chamber as discussed more fully in FIG. 8. Pedestal 41 passes through the central opening 54 (shown in FIG. 6) and lifts wafer 43 from its carrier 40 to place wafer 43 into the chamber and to seal the base against isolation ring 42 of the processing chamber as shown and discussed more fully in connection with FIG. 8.

The specific processing chamber discussed are for illustrative purposes only. It should be understood that any of the various processes that are useful in the making of semiconductor wafers as are well known in the art may be used in the system of this invention.

In FIGS. 8 A, B and C there is illustrated the mechanism for wafer handling in connection with wafer processing in processing chambers. In FIG. 8A there is illustrated a three processor section in which the system operations are at a point where wafers 43 have traveled through chamber transport passages 49 on carriers 40 to new process chambers 18 for processing. The wafers 43 themselves are positioned on subcarriers or chucks 60 that in turn are positioned on carriers 40. This will be clearer in FIG. 8C. The wafer in the preferred embodiment is attached to such a chuck or subcarrier on entering the system at the load lock station or chamber where the chuck is lifted to and attached to the wafer at a position above the carrier at the robot transfer plane. The chuck may be an electrostatic chuck but it may also comprise other chucks of a different type. It remains attached through all process steps and is separated from the wafer at the load lock station as the wafer leaves the system. In turn the wafer on the subcarrier moves through the system on a carrier. Located beneath the carriers and chucks is pedestal 57 housed within bellows 58 to maintain vacuum conditions and to permit elevation of the pedestals to position the wafers into the process chamber for processing. Transfer chamber 15 is illustrated at the end of the processing chambers of the system illustrated.

In FIG. 8B the operational time captured in the two chambers on the left side of this Figure is where the pedestals 57 have entered into and through openings in carriers 40 to elevate wafers 43 to a position for processing in the processing chambers 18. Carriers 40 are resting on drive mechanism 53, which in this embodiment is shown as the preferred magnetic, drive system in which magnetically coupled wheels are employed. This transportation system tends to be less expensive than as compared to robotics which may also be used to transport the substrate to be treated from chamber to chamber.

The details of how the chamber is sealed for process operations within are illustrated in FIG. 8B. Wafer 43 is shown in FIGS. 8A and 8C positioned on an electrostatic chuck 60. A seal 61 is fitted into the edge of chuck 60 and the chamber edge 62 presses against and fits into seal 61 when the wafer is raised into chamber 18 (see FIG. 8B) for processing. Wafer 43 on chuck 60 is shown in an elevated position in the two left-hand illustrated process chambers in FIG. 8B. In the third illustrated process chamber 18 in FIG. 8B the pedestal 57 is shown in a lowered position and the bellows 58 are extended to maintain the area sealed. FIG. 8C illustrates the wafer 43 sitting on the electrostatic chuck 60 on carrier 40 showing also seal 61. Beneath carrier 40 is shown part of drive mechanism 53 used to drive the carrier from chamber to chamber as the wafer moves through the system.

FIG. 9 illustrates transverse or shuttle chamber 15. In this chamber, a wafer is moved in a carrier 40 from a position in alignment with one row of processing chambers to a position in alignment with the next row of chambers. Valves positioned between chambers may be included to separate the wafer in these chambers from the processing ongoing in a row of processing chambers. This can assure the purity of the processes carried on in one row as compared to what is being done in the other row. The carrier in moving from one chamber to the other moves through slot 63. At the base of this unit there are illustrated drive motors 53, which drive the carrier from one chamber to another. In the case of the shuttle at the rear of the unit, both chambers are in high vacuum.

A like chamber can be used at the entrance and exit of the system. In that case the chamber on the left side will normally be the load lock and will comprise the chamber into which the wafer is placed on entering the system and the chamber in which the wafer is introduced to vacuum conditions. On the way out of the system the load lock will be the last chamber the wafer passes through on its way out of the vacuum to atmospheric conditions. In the shuttle, in such a case, the wafer will enter from chamber 30 (see FIGS. 4A and 4B for example) into a holding chamber or pre load lock chamber such as chamber 9 in FIG. 1 and then move from the holding chamber to the load lock from which it will exit the system. The wafer will remain in the holding or pre load lock chamber until the load lock is empty (after a wafer moves from the load lock into chamber 26) at which time it will be moved into position in the load lock to exit the system.

Unique about the system described is that semiconductor wafers or other substrates move simultaneously through the various stations in any row of the equipment. Further a station can differ from an adjacent station in the processes performed during the interval that a wafer is present since stations can be insulated one from another by a valve system between chambers sealing each chamber upon movement of the wafer or other substrate from the chamber to the next chamber or station. Thus a first station may perform an etch process, a second may perform an ion implantation process, a third a chemical vapor deposition process, etc. as to perform all the treatment processes that the wafer or other substrate requires in the process of forming the ultimate product. In some instances this can include a series of chambers performing the same process. This will be the case when the time of dwell within a chamber is less than is required to perform the full process to be performed on the wafer. For example if the dwell time within a chamber is set for a period t and the process, as for example, etching, requires 4t, then etching can be scheduled to be performed in four chambers in sequence before continuing into other process chambers. If it is not required that the full etch be achieved in sequence, then etch chambers may be interposed with other chambers so the wafer is ultimately exposed to four chambers where etching is performed. Since each process chamber is under vacuum, movement of the substrate from a chamber to another will generally not require a full pump down of either of the chambers as each is readied for its next operation.

Significant in this arrangement is that because multiple processes can be performed within the system, a manufacturer need not acquire multiple and different units of equipment. Also by including the various processes in a single piece of equipment there is eliminated the need for transport between separate equipments for different process steps. Also because the various processes are performed in a single unit where all processes may be performed one does not encounter the delays that exist where the wafer is exposed to a process, as for example, etching, in one machine and then is moved from that equipment to another machine, as for example a sputter system, where the wafer sits in inventory as part of a normal delay which is likely to extend for from two to more hours before the wafer is cycled into exposure to a second process. Obviously if a third process is used in existing factories, the need for more equipment, more floor space, more clean rooms, and the delays of transferring wafers between units are all built in expenses in the manufacturing process. In addition some substrates benefit from not being exposed to atmospheric conditions between processes and this too is achieved in the present system and may not be possible where substrates are moved between separate units of equipment. These disadvantages with the present practices are overcome with the described system of this invention.

Although exemplary embodiments of this invention have been shown and described, it will be understood by those skilled in the art that various processes may be employed as are generally used in the manufacture of semiconductor layers and various changes and modifications may be made in the operations and mechanisms of the systems discussed without departing from the scope of the invention as defined in the appended claims.

What is claimed is:

1. A processing system comprising
a load lock chamber for substrates to enter into a vacuum environment, carriers to support substrates to be treated in said processing system, a first row of chambers comprising:
a first processing chamber attached to and horizontally aligned with said load lock to perform a processing step on a substrate in its chamber;
at least a second processing chamber attached to and horizontally aligned with said first processing chamber to perform a second processing step on a substrate in its chamber;
at least a second row of chambers comprising:
processing chambers adjacent to said first row of processing chambers and positioned to a side thereof to further process substrates;
at least one transfer chamber attached to and horizontally aligned with a row of processing chambers at an end thereof and attached to and aligned with another row of processing chambers at an end thereof to transfer a substrate from a row of processing chambers to another row of processing chambers, and
a transport system to move a substrate carrier through said first row of processing chambers, through said transfer chamber and then through said second row of processing chambers,
said processing system occupying substantially the same foot print of said rows of processing chambers and said at least one transfer chamber.

2. A substrate processing system in accordance with claim 1 including a robotic arm arrangement to lift substrates from a cassette and feed substrates into said load lock.

3. A wafer processing system in accordance with claim 2 including said robotic arm arranged to lift wafers from said cassette and feed said wafers into said load lock and return processed wafers from said load lock into said cassette.

4. A substrate processing system in accordance with claim 1 in which the substrates are transported and processed in a horizontal position.

5. A wafer processing system in accordance with claim 3 in which said first row of chambers includes a chamber to sputter deposit material onto the surface of a wafer.

6. A wafer processing system in accordance with claim 3 in which said first row of chambers includes a chamber to etch material from the surface of a wafer.

7. A substrate processing system in accordance with claim 1 in which said carrier has a hole in its central area and in which a lifter moves through the hole and raises the substrate for processing.

8. A wafer processing system in accordance with claim 7 in which the substrate comprises a wafer with an electrostatic chuck attached to the surface with which the lifter makes contact.

9. A substrate processing system in accordance with claim 1 in which valves seal said transfer chamber so that the segment of the transfer chamber in alignment with a row of chambers may be maintained as a distinct environment.

10. A substrate processing system in accordance with claim 1 in which the substrates in said processing stations in said first row of chambers each moves simultaneously with the others to the next chamber in sequence in said first row.

11. A substrate processing system in accordance with claim 1 in which the substrates in said processing stations in said second row of chambers all move simultaneously to the next chamber in sequence in said second row.

12. A wafer processing system in accordance with claim 10 in which said substrates comprise wafers and said transport system sequences the wafers in the said first row of chambers simultaneously to the next chamber in said row when said transport system moves the wafer in said load lock into the first processing chamber.

13. A wafer processing system in accordance with claim 11 in which said substrates comprises wafers and said transport system moves a wafer from a processing chamber in said second row of chambers to a pre-load lock chamber and simultaneously moves other wafers in the said second row of chambers to the next chamber in sequence in said row.

14. A substrate processing system in accordance with claim 10 in which other wafers in the said first row of chambers are sequenced to the next chamber in said row simultaneously with transport of a substrate from a processing chamber in said first row of chambers into a shuttle chamber.

15. A wafer processing system in accordance with claim 14 in which said substrate comprises a wafer and said transport system transports the wafer in the shuttle chamber transversely to a position adjacent to said second row of chambers.

16. A substrate processing system in accordance with claim 1 in which a substrate in a carrier in a sputter station is elevated to a position that seals a processing chamber during sputter operations therein.

17. A processing system in accordance with claim 16 in which said substrate comprises a wafer and the wafer is elevated by being lifted by an arm that presses against the back of the wafer in position in a carrier and extends upward through an opening in said carrier placing the other surface of the wafer in a sealed position at the base of the processing chamber.

18. A wafer processing system in accordance with claim 15 in which the wafer in the shuttle chamber is transported to an adjacent processing chamber in said second row of processing chambers and said other wafers in said second row of chambers each is moved to an adjacent chamber.

19. A substrate processing system in accordance with claim 14 in which said substrate in said pre-load lock station moves into said load lock when substrates in said second row are sequenced to the adjacent processing chambers.

20. A wafer processing system comprising
a robotic wafer handling device to feed wafers from a cassette into a load lock chamber,
a load lock chamber to transfer wafers from atmospheric conditions into
a vacuum environment,
a wafer carrier to support a wafer placed into said load lock through processing chambers and back to said load lock,
a first row of chambers comprising:
a first processing chamber attached to and horizontally aligned with said load lock to perform a wafer processing step on a wafer in its chamber;
at least a second processing chamber attached to and horizontally aligned with said first processing chamber to perform a second processing step on a wafer in its chamber;
a second row of chambers comprising:
at least a third processing chamber adjacent to said at least said second processing chamber and positioned to a side thereof;
at least a forth processing chamber attached to and horizontally aligned with said at least third processing chamber;
a transfer chamber attached to and horizontally aligned with said first row of processing chambers at an end thereof and attached to and aligned with said second row of processing chambers at an end thereof to transfer a wafer from said first row of processing chambers to said second row of processing chambers, and
a transport system to move said wafer carrier from said load lock through said first row of processing chambers, through said transfer chamber and then through said second row of processing chambers and back to said load lock to exit to atmospheric conditions, said wafer processing system occupying substantially the same foot print of said aligned load lock, said first and second row of processing chambers and said transfer chamber.

21. A wafer processing system in accordance with claim 20 in which a chuck is affixed to the rear of a wafer when the wafer is placed into said carrier.

22. A wafer processing system in accordance with claim 20 including a pre load lock chamber aligned with said second row of chambers in the path between the final processing chamber on said row and said load lock in said first row for transport of a processed wafer to await transport into said load lock.

23. A wafer processing system in accordance with claim 20 in which at least two adjacent process chambers of said first row perform the same process.

24. A wafer processing system in accordance with claim 20 in which two adjacent process chambers in said first row perform different processes under vacuum.

25. A wafer processing system in accordance with claim 20 in which two adjacent process chambers in said second row perform the same process.

26. A wafer processing system in accordance with claim 20 in which said transport system moves wafers in said first row simultaneously in the same direction to adjacent chambers in said first row.

27. A wafer processing system in accordance with claim 20 in which said transport system moves wafers in said second row simultaneously in the same direction to adjacent chambers in said second row.

28. A wafer processing system in accordance with claim 20 in which said transport system sequences wafers into adjacent processing chambers after the same time interval in said first row.

29. A wafer processing system in accordance with claim 20 in which said transport system sequences wafers into adjacent processing chambers after the same time interval in said second row.

30. A wafer processing system in accordance with claim 20 in which at least two adjacent chambers are insulated from one another during processing within the chambers.

31. A wafer processing system in accordance with claim 20 in which in a sequence of three chambers the central chamber is an insulating chamber between the two surrounding chambers.

32. A wafer processing system in accordance with claim 3 in which one of said chambers includes a chamber for metalization of a wafer.

33. A wafer processing system in accordance with claim 3 in which one of said chambers includes a chamber for ion implantation of a wafer.

34. A wafer processing system in accordance with claim 3 in which one of said chambers includes a chamber to clean the surface of a wafer.

35. A wafer processing system in accordance with claim 3 in which one of said chambers includes a chamber to thermally treat a wafer.

36. A wafer processing system in accordance with claim 8 in which said lifter comprises a pedestal on a rod enclosed within the system and in which the pedestal presses against the chuck supporting the wafer.

37. A wafer processing system in accordance with claim 8 in which said lifter raises the wafer to a position adjacent to an isolation ring and seals the chamber by contacting a seal against the chuck.

38. A method of manufacturing wafers into manufactured products by subjecting wafers to a sequence of processing operations for the same period of time comprising moving wafers to be processed into a system having a plurality of processing chambers, processing at least two wafers simultaneously in processing chambers for the same time period, transporting wafers into a chamber to be processed and then out of said chamber after processing, repeating the step of processing the wafer in a new chamber and moving the wafer from said new chamber following processing therein, transport and processing being performed in a vacuum environment, maintaining the wafers in a horizontal position during processing in said processing chambers, and manufacturing said wafers into manufactured products in a physical area that is substantially the size of the processing chambers.

39. The method of claim 38 in which wafer processing is by more than a single wafer processing technology.

40. The method of claim 38 including exposing the wafer to an etch process and a cleaning process.

41. The method of claim 38 including exposing the wafer to an etch process and a metalization process.

42. The method of claim 38 including exposing the wafer to at least an ion implantation process.

43. The method of claim 38 including exposing the wafer to at least a sputtering process.

44. The method of claim 43 including exposing the wafer also to a thermal treatment process.

45. The method of claim 42 including exposing the wafer also to a thermal treatment process.

46. The method of claim 38 including depositing materials on the surface of the wafer by at least exposing the wafer to a chemical vapor deposition process.
